(19) United States
(12) Patent Application Publication
(10) Pub. No.: US 2009/0029532 A1
(43) Pub. Date: Jan. 29, 2009

(54) Method for forming a microcrystalline silicon film

(75) Inventors: Jung-Jie Huang, Hsin Chu Hsien (TW); Cheng-Ju Tsai, Hsin Chu Hsien (TW); Yung-Hui Yeh, Hsin Chu Hsien (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 12/005,270

(22) Filed: Dec. 27, 2007

(30) Foreign Application Priority Data
Jul. 23, 2007 (TW) 96126800

(51) Int. Cl. H01L 21/363

(52) U.S. Cl. 438/479; 257/E21.462

(57) ABSTRACT

This invention provides a method for forming a microcrystalline silicon film, which employs a three-stage deposition process to form a microcrystalline film. A microcrystalline silicon seed layer is formed on a substrate. Gaseous ions are used to bombard a surface of the microcrystalline silicon seed layer. Microcrystalline silicon is formed on the microcrystalline silicon seed layer after the bombardment to a predetermined thickness.

### BACKGROUND OF THE INVENTION

1. Field of the Invention

This invention relates to a method for forming a microcrystalline silicon film, and more particularly to a method using a three-stage deposition process for forming a microcrystalline silicon film.

2. Description of the Related Art

Compared to a conventional amorphous silicon thin-film transistor (a-Si TFT), a low-temperature polycrystalline silicon thin-film transistor (LTPS-TFT) has a higher electron mobility and better reliability. Generally, a process of solid phase crystallization (SPC) or excimer laser annealing (ELA) is utilized for forming a polycrystalline silicon thin-film, wherein an amorphous silicon (a-Si:H) material is crystallized into a polycrystalline silicon (Poly-Si) by high-temperature annealing. However, the SPC process requires a higher crystallization temperature and thus needs silicon wafers or quartz glass as the substrates, which is expensive and unfavorable for large-area mass productions. As regards the ELA process, thought it requires a lower crystallization temperature, the machine for ELA process has a problem of high cost and poor productivity nonetheless. According to certain previous researches, the cost of production can be immensely reduced if a process of plasma-enhanced chemical vapor deposition (PECVD) is applied to deposit a low-temperature polycrystalline material directly. PECVD is thus a rather applicable process for forming polycrystalline silicon thin-films. Among the manufacturing devices for directly depositing microcrystalline silicon thin films, high density plasma chemical vapor deposition (HDP CVD) system, e.g. inductively coupled plasma chemical vapor deposition (ICP CVD) system, and PECVD system are two major systems. Although a microcrystalline silicon thin film with a high crystallization rate can be grown in a HDP CVD system, the thin films produced are damaged by the plasma more severely; in addition, the manufacturing device is unfavorable for large-area mass production. In contrast, a PECVD system, the most common system utilized for manufacturing a-Si TFTs, is favorable for large-area mass production; also, the thin films produced are damaged by the plasma more slightly. PECVD, thus, will be a field worth research and development. A conventional PECVD process, however, has certain disadvantages of slow deposition and low crystallization rate, and needs further development and improvement therefore.

A conventional PECVD process forms a microcrystalline silicon thin film by using chiefly a high-density (>95%) hydrogen gas mixed with a diluted silane (SiH₄) gas. The hydrogen gas is used to erode the weak Si—Si bonds and further produces a thin silicon film of microcrystals. With this method, the deposition rate of forming a microcrystalline silicon thin film is slow and the crystallization rate is low. There is another method utilizing a layer-by-layer deposition technique to form a microcrystalline silicon thin film. The method deposits the thin film by periodically providing silane gas into the process. The disadvantage of this method lies in slow deposition rate, which is slower than 0.1 nm per second and unfavorable for mass production. Yet another method for forming a microcrystalline silicon thin film is to introduce silane, argon and hydrogen gases into the deposition system simultaneously, using argon ions to bombard the surface of the thin film so that the crystallization rate is raised. This method employs a single step of direct deposition, and the microcrystalline silicon thin film formed has a poorer crystallization rate.

Therefore, it is desirable to provide an improved method for forming a microcrystalline silicon thin film that overcomes the disadvantages caused by conventional forming process.

### SUMMARY OF THE INVENTION

The present invention provides a method for forming a microcrystalline silicon thin film, which employs a three-stage deposition process to form a microcrystalline silicon thin film with higher crystallization at a low temperature and a faster deposition rate.

The method for forming a microcrystalline silicon thin film of the present invention includes providing a substrate, forming a microcrystalline silicon seed layer on the substrate, using gaseous ions to bombard the microcrystalline silicon seed layer, and forming microcrystalline silicon to a predetermined thickness on the microcrystalline silicon seed layer. In the present invention, the gaseous ions are used to bombard the microcrystalline silicon seed layer so that it obtains a better crystallinity. The follow-up crystallization rate of the microcrystalline silicon thin films formed on the microcrystalline silicon seed layer, thus, can be increased. Inert gas ions introduced during the process also increase the deposition rate of the microcrystalline silicon thin films.

### BRIEF DESCRIPTION OF THE DRAWINGS

FIG. 1 is a flow chart showing a process of forming a microcystalline silicon thin film of the present invention;

FIG. 2A through FIG. 2C is schematic views for growing the microcrystalline silicon thin film, which respectively correspond to various steps of the process flow of FIG. 1;

FIG. 3A is a Raman spectrum of growing the microcrystalline silicon thin film without ion bombardment;

FIG. 3B is a Raman spectrum of growing the microcrystalline silicon thin film with ion bombardment;

FIG. 4A is a scanning electron microscope image (SEM image) of the microcrystalline silicon thin film of FIG. 3A; and

FIG. 4B is a SEM image of the microcrystalline silicon thin film of FIG. 3B.

### DETAILED DESCRIPTION OF THE PREFERRED EMBODIMENT

The present invention provides a method for forming a microcrystalline silicon thin film, employing a three-stage deposition process. At first, a microcrystalline silicon seed layer is deposited. Subsequently, ion bombardment is performed unto the microcrystalline silicon seed layer so that it obtains better crystallinity. Then, microcrystalline silicon is deposited on the microcrystalline silicon seed layer after bombardment, and a microcrystalline silicon thin film of a predetermined thickness is thus formed.

The method for forming a microcrystalline silicon thin film of the present invention will be described in details with following preferred embodiments and accompanying drawings.

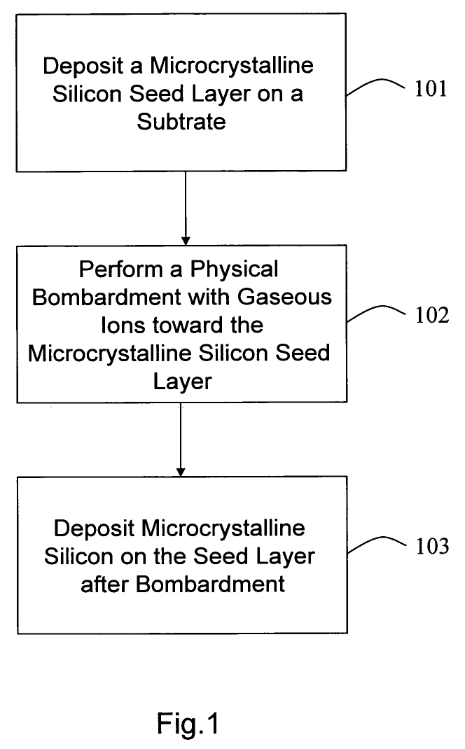

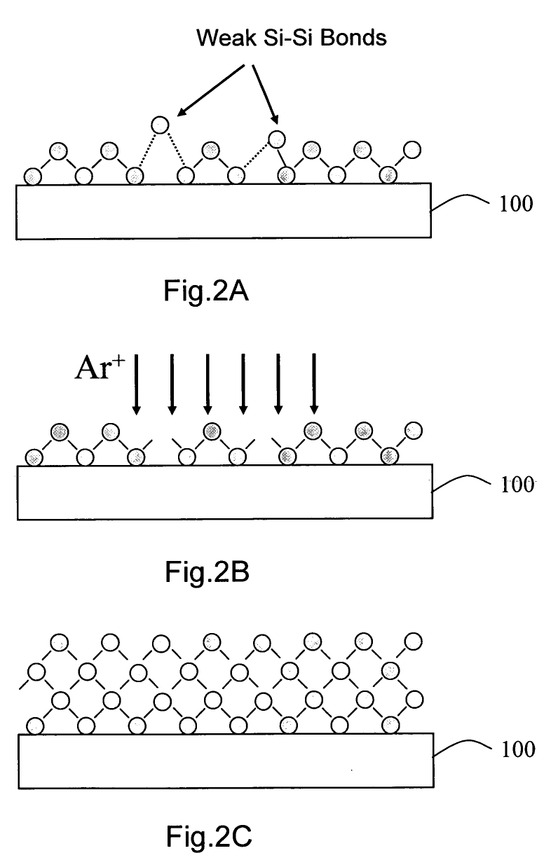

FIG. 1 is a process flow according to one preferred embodiment of the present invention. FIG. 2A through FIG. 2C is schematic views of growing the microcrystalline silicon thin film, which respectively correspond to various steps of the process flow of FIG. 1. Reference is now made to FIG. 1 and FIG. 2A through FIG. 2C. In step 101, a thin microcrystalline silicon seed layer of less than 10 nm is formed on a substrate 100, as shown in FIG. 2A. In this preferred embodiment, silane (SiH₄), hydrogen (H₂) and argon (Ar) are introduced as process gases, and the microcrystalline silicon seed layer is deposited on the substrate 100 by plasma-enhanced chemical vapor deposition (PECVD). In this process, silane is a primary source of producing silicon, hydrogen is a dilution gas for etching silicon-silicon (Si—Si) weak bonds and for passivation defects of the thin silicon film, and argon is used for increasing a dissociation rate of reactive gases and for etching the silicon-silicon weak bonds. Materials used as the substrate for forming the microcrystalline silicon thin film of the present invention can be silicon wafers, metal foil, glass or plastics. Then, in step 102, the supply of silane as a process gas is turned off, and physical bombardment using hydrogen gas and argon ions (Ar⁺) is performed onto the surface of the microcrystalline silicon seed layer, as shown in FIG. 2B. The weak Si—Si bonds on the surface of the microcrystalline silicon seed layer are thus broken, which helps the seed layer obtain better crystallinity. The follow-up crystallization rate of depositing microcrystalline silicon thin films then can be increased. Argon ions will be helpful in achieving better bombardment effects and increasing crystallinity during the process since they are inert and have larger atoms. Further, in step 103, silane (SiH₄), hydrogen (H₂) and argon are introduced again as process gases, and microcrystalline silicon keeps on depositing on the microcrystalline silicon seed layer by PECVD. A microcrystalline silicon thin film is formed to a predetermined thickness, wherein deposition is at a rate of between approximately 4 and 5 angstroms per second, as shown in FIG. 2C.

In the method for forming microcrystalline silicon thin film of the present invention, silane (SiH₄), hydrogen (H₂), and argon are used as process gases, while silicon tetrafluoride (SiF₄) or dichlorosilane (SiH₂Cl₂) can also be added during the process as a source gas of silicon. Argon is used as an inert gas which, otherwise, can be helium (He), neon (Ne), krypton (Kr) or xenon (Xe). Furthermore, a phosphine (PH₃) gas can be added in steps 101 and 103 if an N⁺ microcrystalline silicon thin film is to be formed. Diborane (B₂H₆) gas can be added in steps 101 and 103 if a P⁺ microcrystalline silicon thin film is to be formed.

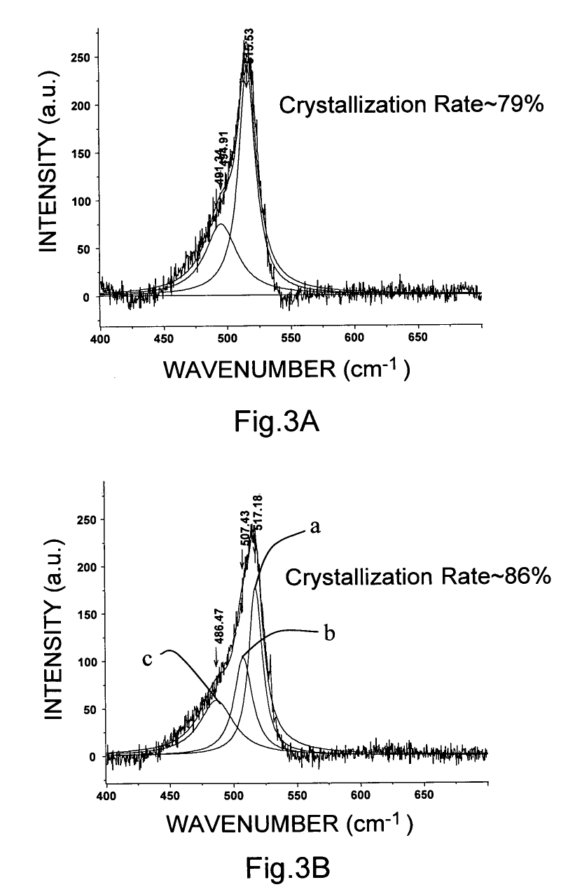

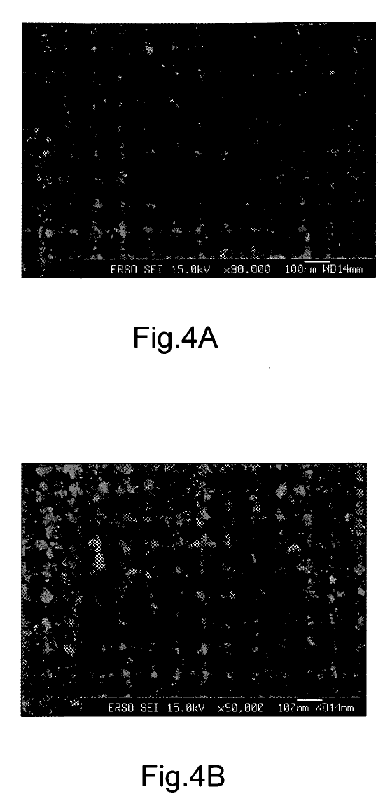

In step 102, the present invention uses the ion bombardment technique to increase the crystallinity of microcrystalline silicon grown on the seed layer. FIG. 3A and FIG. 3B respectively illustrates the Raman spectra of growing the microcrystalline silicon thin film without and with the technique of ion bombardment. Both of the two microcrystalline silicon thin films are 200 nm thick. It is apparent from these two figures that better crystallinity is obtained by growing the microcrystalline silicon thin film with ion bombardment, wherein the crystallization rate increases from 79% (FIG. 3A) to 86% (FIG. 3B). As shown in FIG. 3B, peak a represents the peak of microcrystalline silicon, peak b represents the peak of Si between a-Si and microcrystalline silicon, and peak c represents the peak of a-Si. The crystallization rate of the microcrystalline silicon thin film is (a+b)/(a+b+0.8×c). FIG. 4A and FIG. 4B are Scanning Electron Microscope (SEM) images respectively corresponding to FIG. 3A and FIG. 3B. It is also apparent from these images that better crystallinity is obtained by growing the microcrystalline silicon thin film with ion bombardment used in the present invention.

The present invention uses a three-stage deposition process, e.g. PECVD, to grow microcrystalline silicon thin films at low temperatures. This process leads to a faster deposition rate and a higher crystallization rate for microcrystalline silicon thin films, and is thus favorable for large-area mass productions.

While the invention has been described by way of examples and in terms of preferred embodiments, it is to be understood that those who are familiar with the subject art can carry out various modifications and similar arrangements and procedures described in the present invention and also achieve the effectiveness of the present invention. Hence, it is to be understood that the description of the present invention should be accorded with the broadest interpretation to those who are familiar with the subject art, and the invention is not limited thereto.

What is claimed is:

1. A method for forming a microcrystalline silicon thin film, comprising:
providing a substrate;
forming a microcrystalline silicon seed layer on said substrate;
bombarding said microcrystalline silicon seed layer with gaseous ions; and
forming microcrystalline silicon to a predetermined thickness on said microcrystalline silicon seed layer after bombardment.

2. The method of claim 1, wherein said substrate comprises silicon wafer, metal foil, glass or plastic.

3. The method of claim 1, wherein said microcrystalline silicon seed layer is physically bombarded by the gaseous ions.

4. The method of claim 1, wherein said microcrystalline silicon seed layer is formed by plasma-enhanced chemical vapor deposition.

5. The method of claim 1, wherein said microcrystalline silicon is formed on said microcrystalline silicon seed layer after the bombardment by plasma-enhanced chemical vapor deposition.

6. The method of claim 4, wherein said microcrystalline silicon is formed on said microcrystalline silicon seed layer after the bombardment by plasma-enhanced chemical vapor deposition.

7. The method of claim 1, wherein process gases for forming said microcrystalline silicon seed layer comprises silane, hydrogen gas and an inert gas.

8. The method of claim 1, wherein process gases for forming said microcrystalline silicon comprise silane, hydrogen gas and an inert gas.

9. The method of claim 7, wherein process gases for forming said microcrystalline silicon comprise silane, hydrogen gas and an inert gas.

10. The method of claim 7, wherein process gases for forming said microcrystalline silicon seed layer further comprise silicon tetrafluoride (SiF₄) or dichlorosilane (SiH₂Cl₂).

11. The method of claim 8, wherein process gases for forming said microcrystalline silicon further comprise silicon tetrafluoride (SiF₄) or dichlorosilane (SiH₂Cl₂).

12. The method of claim 7, wherein said inert gas comprises helium (He), neon (Ne), argon (Ar), krypton (Kr) or xenon (Xe).

13. The method of claim 9, wherein phosphine (PH₃) gas is added during the processes of forming said microcrystalline silicon seed layer and said microcrystalline silicon to grow an N⁺ microcrystalline silicon thin film.

14. The method of claim 9, wherein diborane (B₂H₆) gas is added during the processes of forming said microcrystalline silicon seed layer and said microcrystalline silicon to grow a P⁺ microcrystalline silicon thin film.

15. The method of claim 1, wherein a thickness of said microcrystalline silicon seed layer is less than 10 nm.
